(19) United States
(12) Patent Application Publication
(10) Pub. No.: US 2026/0066886 A1
(43) Pub. Date: Mar. 5, 2026

(54) INTERNAL CLOCK SIGNAL SKEW MEASUREMENT CIRCUITRY

(71) Applicant: XILINX, INC., San Jose, CA (US)

(72) Inventor: Hui LI, San Jose, CA (US)

(21) Appl. No.: 18/817,178

(22) Filed: Aug. 27, 2024

(51) Int. Cl. H03K 5/135; G01R 31/317; G06F 1/10

(52) U.S. Cl. CPC H03K 5/135; G01R 31/31725; G06F 1/10

(57) ABSTRACT

Clock skew measurement circuitry determines skew between clock signals within an integrated circuit (IC) device or between multiple IC devices. An IC device includes clock tree circuitry and the clock skew measurement circuitry. The clock tree circuitry provides a first clock signal and a second clock signal to components of the IC device. The clock skew measurement circuitry is connected to the clock tree circuitry. The clock skew measurement circuitry generates and outputs an error signal based on a phase difference between the first clock signal and the second clock signal.

### TECHNICAL FIELD

Examples of the present disclosure generally relate to a measurement circuitry for determining skew between clock signals internal to an integrated circuit device.

### BACKGROUND

In an integrated circuit (IC) device utilize various clock signals during operations. The clock signals are communicated via clock trees to components of the IC device. In an IC device, overestimating the skew (e.g., a difference in arrival timing) within the clock signals during the design process may degrade the performance of the IC device. Skew may be mitigated by calibrating skew of an IC device and using the calibration result to generate a balanced clock tree design. However, in a programmable IC device, the clock tree of the IC device may change. Accordingly, the calibration result may not be usable to generate a balanced clock tree design. Alternatively, a programmable circuit internal to the IC device may be used to determine skew. However, the parameters of the programmable circuit and/or limitations of the location program circuit may not accurately determine the skew of the internal clock signals.

### SUMMARY

In one example, an integrated circuit (IC) device includes clock tree circuitry and clock skew measurement circuitry. The clock tree circuitry provides a first clock signal and a second clock signal to components of the IC device. The clock skew measurement circuitry is connected to the clock tree circuitry. The clock skew measurement circuitry generates and outputs an error signal based on a phase difference between the first clock signal and the second clock signal

In one example, an electronic device includes a first IC device. The first IC device includes clock tree circuitry and clock skew measurement circuitry. The clock tree circuitry provides a first clock signal and a second clock signal to components of the IC device. The clock skew measurement circuitry is connected to the clock tree circuitry. The clock skew measurement circuitry generates and outputs an error signal based on a phase difference between the first clock signal and the second clock signal.

In one example, a method includes receiving, at clock skew measurement circuitry of a first IC device, a first clock signal and a second clock signal from clock tree circuitry of the IC device. The method further includes generating and outputting, via the clock skew measurement circuitry, an error signal based on a phase difference between the first clock signal and the second clock signal.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a block diagram of an integrated circuit (IC) device.

FIG. 2A illustrates a block diagram of an electronic device having multiple IC devices.

FIG. 2B illustrates a block diagram of an electronic device having multiple IC devices.

FIG. 3 illustrates a block diagram of a portion of an IC device.

FIG. 4 illustrates a block diagram of a portion of a first IC device and a portion of a second IC device.

FIG. 5A illustrates a block diagram of clock skew measurement circuitry.

FIG. 5B illustrates a block diagram of clock skew measurement circuitry.

FIG. 6A illustrates a block diagram of delay circuitry.

FIG. 6B illustrates a block diagram of coarse delay circuitry.

FIG. 7 illustrates a time line of waveforms of start and stop signals of delay circuitry.

FIG. 8 illustrates flowchart of a method for determining skew (e.g., an arrival time difference) between clock signals.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

An integrated circuit (IC) device includes components that are operated via one or more clock signals. The clock signals are provided to the components via clock trees of the IC device. Skew (e.g., a timing difference) between clock signals is determined and mitigated to improve timing performance of the IC device. In one or more examples, the IC device is a programmable IC device having a programmable clock network. In a programmable clock network, changes to the programmable clock network changes the skew between the clock signals of the clock network. However, current approaches for determining the clock skew are not able to determine changes in skew between clock signals based on changes to the programmable clock network. Current approaches for mitigating clock skew use a balanced clock tree, which may not be adaptable based on changes to the clock network and corresponding clock skew. Additionally, or alternatively, the current programmable circuits for measuring clock skew may not be able to accurately determine the clock skew due to inaccurate parameters and/or the location of the clock skew measuring circuits.

In the following, clock skew determination circuitry that is able to measure changes in clock skew when there changes to a clock network and/or accurately measure clock skew of clock signals internal to an IC device. The clock skew determination circuitry is positioned between clock tree leafs within an IC device. The clock skew determination circuitry receives the leaf clock signals from the clock tree leafs and determines the skew between the clock leafs. A leaf clock signal is the final stage clock signal of a corresponding clock tree. In one or more examples, the clock skew determination circuitry is positioned at the boundary between two IC devices. In such an example, the clock skew determination circuitry is used to determine skew between leaf clock signals of the two IC devices. The clock skew is determined between different clock signals (e.g., leaf clock signals) within common clock domain. The clock skew may be used to mitigate clock skew within an IC device and/or between an IC device by adjusting parameters of a clock signals, a clock tree, and/or a design of an IC device.

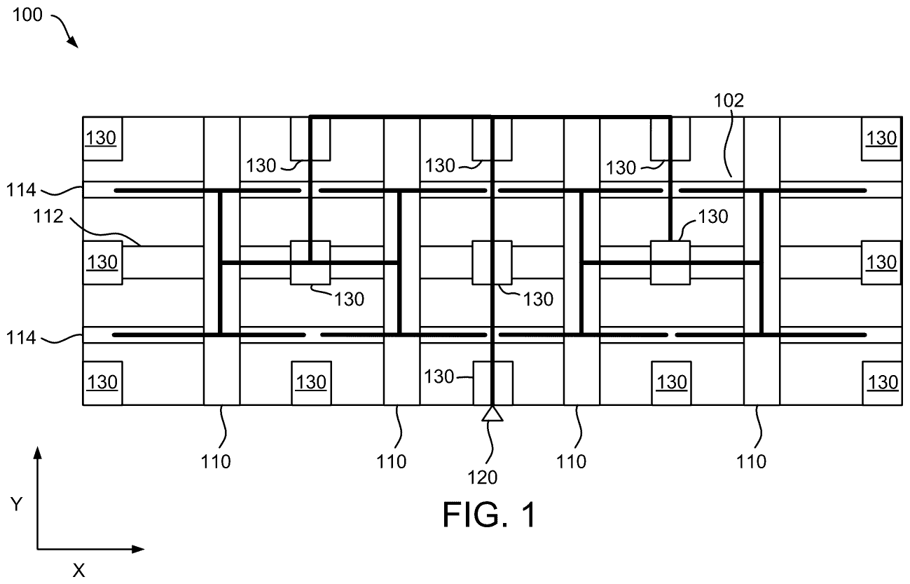

FIG. 1 is a block diagram depicting an exemplary integrated circuit (IC) device 100, according to one or more examples. The IC device 100 may be an IC device of an electronic device. In one example, the IC device 100 is a programmable IC device (e.g., a field programmable gate array (FPGA) or another programmable IC device), a processing device (e.g., a central processing unit (CPU) or a graphics processing unit (GPU), among others), a memory device, or another type of IC device. In one example, the IC device 100 is a programmable device having an array of programmable logic resources. The programmable resources include, but are not limited to configurable logic blocks (CLBs), programmable logic array blocks (LABS), or other form of fabric sub-regions (FSRs).

The IC device 100 includes vertical network-on-chip (VNOC) circuitry 110 and horizontal network-on-chip (HNOC) circuitry 112. The VNOC circuitry 110 and the HNOC circuitry 112 form a NOC circuitry of the IC device. In one example, the VNOC circuitry 110 includes one or more vertically routed channels (e.g., routed in a Y direction). The HNOC circuitry 112 includes one or more horizontally routed channels (e.g., routed in an X direction). In one or more examples, the VNOC circuitry 110 and the HNOC circuitries 112 are configured to transmit data from one location to another location of the IC device 100 (or other ICs formed in an electronic device). In one example, the IC device 100 further includes RCLK channel circuitry 114. The RCLK channel circuitry 114 is formed horizontally (e.g., in the X direction) across the IC device 100. The RCLK channel circuitry 114 may be formed across a portion of the resources of the IC device, and provides the clock signal to the resources

In one or more examples, clock signals are transmitted via the VNOC circuitry 110, the HNOC circuitry 112, and the RCLK channel circuitry 114. In such an example, the VNOC circuitry 110, the HNOC circuitry 112, and the RCLK channel circuitry 114 form at least part of the clock tree circuitry 102 of the IC device 100. In one or more examples, IC device 100 may be coupled to a clock source (e.g., clock source 120) provided by an external clock circuitry that is provided (i.e., routed) to clock tree circuitry 102 of the IC device.

A clock tree circuitry 102 receives a clock signal via a clock source (e.g., the clock source 120). The clock tree circuitry 102 includes one or more routing tracks within the IC device 100. The routing tracks may be routed in a horizontal (or X) direction and/or a vertical (or Y) direction.

The clock tree circuitry 102 may include one or more regional clock circuitries. A regional clock circuitry includes different types of routing tracks used to route a leaf clock signal to clock leafs within regional resources of the IC device 100. In one or more examples, the clock tree circuitry 102 includes routing tracks within the VNOC circuitry 110, the HNOC circuitry 112, and/or the RCLK channel circuitry 114. In one or more examples, the clock tree circuitry 102 is coupled to (or is also part of) a global clock circuitry of the IC device 100. In one or more examples, the clock tree circuitry 102 is used to distribute (i.e., branches out) the clock signal received from the global clock circuitry to the corresponding resources of the IC device 100.

In one or more examples, the horizontal routing tracks and the vertical routing tracks may also be described herein collectively as “clock route resources.” In an example, the horizontal routing tracks and/or the vertical routing tracks are segmented at boundaries of resources. In one or more examples, the horizontal routing tracks and/or the vertical routing tracks provide bidirectional communication. In one or more examples, the clock tree circuitry 102 further includes one or more distribution tracks and one or more spines. Spines are clock tree resources that branch out from the clock tree circuitry 102 and distribution tracks are clock tree resources that branch out from the spines to provide the clock signal to corresponding resources. Any combination of routing tracks, distribution tracks, and spines may be used to route the clock signal to one or more of the resources 203.

In one or more examples, the clock tree and clock route resources are able to extend to other IC devices, allowing for a global clock circuitry between IC devices to be formed.

The IC device 100 further includes one or more clock skew measurement circuitries 130. A clock skew measurement circuitry 130 determines differences between two or more clock signals. The difference may be a difference in an arrival time of the clock signals. In one or more examples, the difference in arrival time may be referred to as clock skew. The clock skew measurement circuitry 130 determines the skew between two or more local (or leaf) clock signals by determining a difference phase between the two or more local (or leaf) clock signals. The clock skew measurement circuitry 130 determines the skew between local clock signals internal to the IC device 100 based on a phase difference between the local clock signal. In one example, a clock skew measurement circuitry 130 is positioned (disposed) at the boundary between two or more clock signals (clock domains). In one or more examples, a clock skew measurement circuitry 130 is positioned at the boundary between two IC devices. For example, a clock skew measurement circuitry 130 is positioned where clock signals are communicated between two IC devices. In one example, the positioning of the clock skew measurement circuitry 130 allows for the clock skew measurement circuitry 130 to receive a clock signal, or clock signals, from another IC device to determine the skew (e.g., arrival timing differences) of the clock signals of the two IC devices based on a difference in phase between the clock signals.

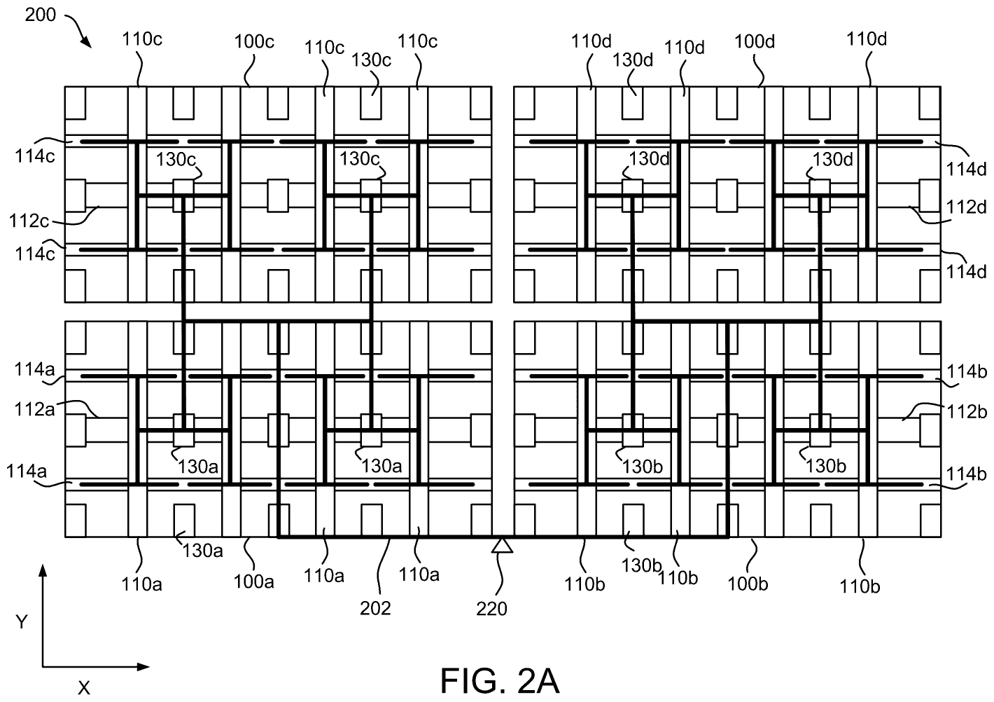

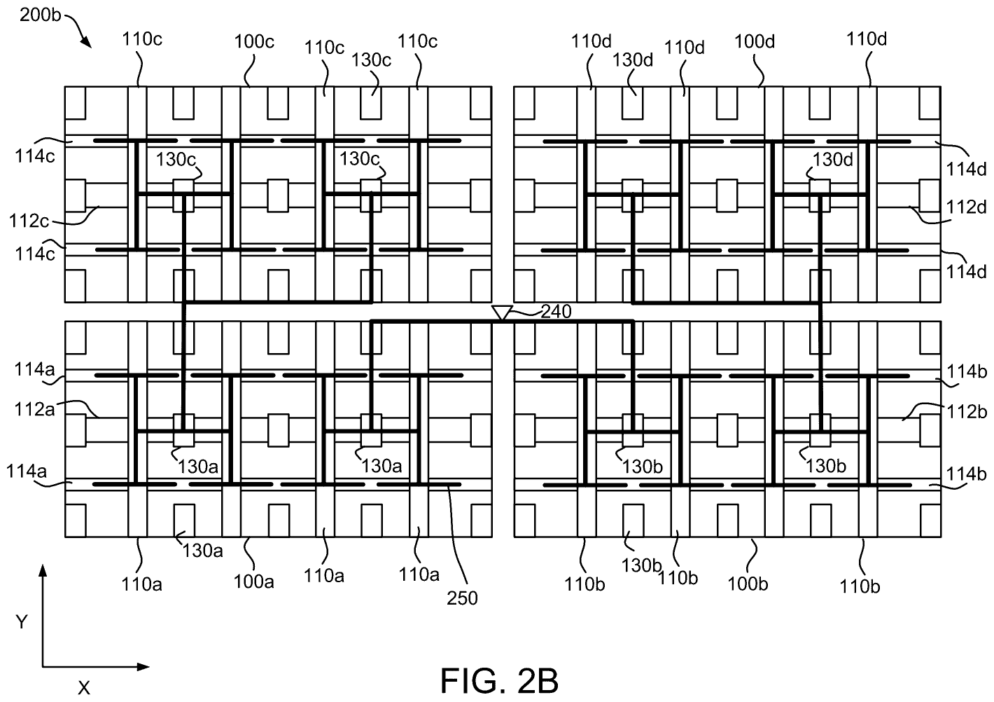

FIG. 2A illustrates an electronic device 200, according to one or more examples. The electronic device 200 includes IC devices 100a-100d. In other examples, an electronic device may include more than or less than four IC devices. The IC devices 100a-100d are configured similar to the IC device 100 of FIG. 1. The IC device 100a includes VNOC circuitry 110a, HNOC circuitry 112a, RCLK channel circuitry 114a, and clock skew measurement circuitry 130a. The IC device 100b includes VNOC circuitry 110b, HNOC circuitry 112b, RCLK channel circuitry 114b, and clock skew measurement circuitry 130b. The IC device 100c includes VNOC circuitry 110c, HNOC circuitry 112c, RCLK channel circuitry 114c, and clock skew measurement circuitry 130c. The IC device 100d includes VNOC circuitry 110d, HNOC circuitry 112d, RCLK channel circuitry 114d, and clock skew measurement circuitry 130d.

The clock tree 202 is routed within and between each of the IC devices 100a-100d. In one or more examples, the clock tree 202 routes one or more clock signals between the global clock source 220 and resources of the IC devices 100a-100d along the VNOC circuitry 110, the HNOC circuitry 112, and RCLK channel circuitry 114 of each IC device 100. In one example, a first clock skew measurement circuitry 130a of the IC device 100a determines a skew between two or more clock signals within the IC device 100a, and a second clock skew measurement circuitry 130a along a boundary of the IC device 100a is used to determine a skew between clock signals communicated between the IC device 100a and another IC device (e.g., the IC device 100b or the IC device 100c). A first clock skew measurement circuitry 130b of the IC device 100b determines a skew between two or more clock signals within the IC device 100b, and a second clock skew measurement circuitry 130b along a boundary of the IC device 100b is used to determine a skew between clock signals communicated between the IC device 100b and another IC device (e.g., the IC device 100a or the IC device 100d). A first clock skew measurement circuitry 130c of the IC device 100c determines a skew between two or more clock signals within the IC device 100c, and a second clock skew measurement circuitry 130c along a boundary of the IC device 100c is used to determine a skew between clock signals communicated between the IC device 100c and another IC device (e.g., the IC device 100a or the IC device 100d). A first clock skew measurement circuitry 130d of the IC device 100d determines a skew between two or more clock signals within the IC device 100dc, and a second clock skew measurement circuitry 130d along a boundary of the IC device 100d is used to determine a skew between clock signals communicated between the IC device 100d and another IC device (e.g., the IC device 100c or the IC device 100b). In one example, to determine the skew a phase difference between the two clock signals is determined.

FIG. 2B illustrates an electronic device 200b, according to one or more examples. The electronic device 200b includes IC devices 100a-100d. The IC devices 100a-100d are configured similar to the IC device 100 of FIG. 1. In the electronic device 200b, the clock tree 250 is routed within and between each of the IC devices 100a-100d. In one or more examples, the clock tree 250 routes one or more clock signals between the global clock source 240 and resources of the IC devices 100a-100d along the VNOC circuitry 110, the HNOC circuitry 112, and RCLK channel circuitry 114 of each IC device 100. The clock tree 250 is configured similar to the clock tree 202 of FIG. 2A. In one example, the clock tree 250 has a different shape from the clock tree 202 of FIG. 2A. For example, the vertical and/or horizontal routing tracks of the clock tree 250 differ from than that used to form the clock tree 202 of FIG. 2A. The clock skew measurement circuitries 130 are used to determine skew of clock signals within an IC device 100a-100d and/or between IC devices 100a-100d as is described above with regard to FIG. 1 and FIG. 2A.

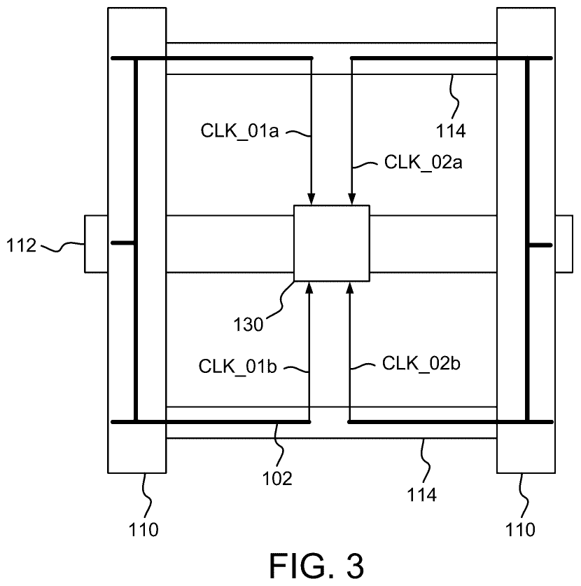

FIG. 3 illustrates a portion of an IC device (e.g., the IC device 100 of FIG. 1). The clock skew measurement circuitry 130 determines a skew between leaf clock signals CLK_01a and CLK_01b and between leaf clock signals CLK_02a and CLK_02b. The leaf clock signals are derived from a clock signal received at a global clock source (e.g., the clock source 120 of FIG. 1). In one example, the clock skew measurement circuitry 130 receives the clock signals CLK_01a, CLK_01b, CLK_02a, and CLK_02b. As is described in greater detail in the following, the clock skew measurement circuitry 130 determines a skew between the clock signals CLK_01a and CLK_01b based on a determined difference in arrival time of the clock signals.

The determined difference in arrival time is determined based on a difference in phase of the clock signals. Further, the clock skew measurement circuitry 130 determines a skew between the clock signals CLK_02a and CLK_02b based on a determined difference in arrival time of the clock signals. The determined difference in arrival time is determined based on a difference in phase of the clock signals. In one example, the clock skew measurement circuitry 130 is connected to the clock tree circuitry 102 to receive the clock signals CLK_01a, CLK_01b, CLK_02a, and CLK_02b. For example, the clock skew measurement circuitry 130 is connected to the RCLK channel circuitry 114 via one or more routings. The clock skew measurement circuitry 130 receives the clock signals CLK_01a, CLK_01b, CLK_02a, and CLK_02b via the routings.

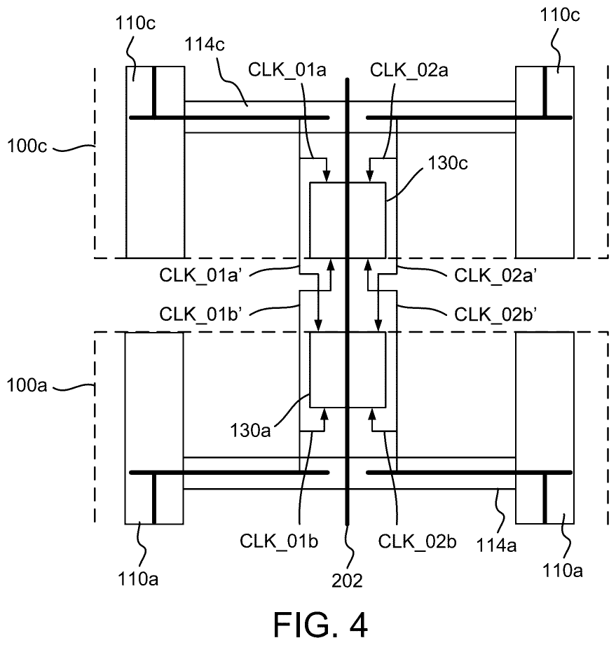

FIG. 4 illustrates a portion of a first and second IC device (e.g., the IC device 100a and the IC device 100c of FIG. 1). The clock skew measurement circuitries 130a and 130c determine the skew between leaf clock signals that are communicated between IC devices 100a and 100c and local IC devices. In one example, the skew between leaf clock signal is determined difference in arrival time is determined based on a difference in phase of the clock signals. For example, the clock skew measurement circuitry 130c determines a skew between regional (leaf) clock signals CLK_01a and CLK_01b′ received from the IC device 100a and between leaf clock signals CLK_02a and CLK_02b′ received from the IC device 100a. The clock skew measurement circuitry 130a determines a skew between leaf clock signals CLK_01b and CLK_01a′ received from the IC device 100c and between leaf clock signals CLK_02b and CLK_0a′ received from the IC device 100c. The leaf clock signals are derived from a clock signal received at a global clock source (e.g., the global clock source 220 of FIG. 2A or the global clock source 240 of FIG. 2B). In one example, the clock skew measurement circuitry 130c receives the clock signals CLK_01a, CLK_01b′, CLK_02a, and CLK_02b′. As is described in greater detail in the following, the clock skew measurement circuitry 130 determines a skew between the clock signals CLK_01a and CLK_01b′ based on a determined difference in arrival time of the clock signals. Further, the clock skew measurement circuitry 130c determines a skew between the clock signals CLK_02a and CLK_02b′ based on a determined difference in arrival time of the clock signals. In one example, the clock skew measurement circuitry 130a is connected to the RCLK channel circuitries 114a and 114c via one or more routings and/or inter IC device connections. The clock skew measurement circuitry 130a receives the clock signals CLK_01b, CLK_01a′, CLK_02b, and CLK_02a′ via the routings and/or inter IC device connections. The clock skew measurement circuitry 130a determines a skew between the clock signals CLK_0ba and CLK_01a′ based on a determined difference in arrival time of the clock signals. Further, the clock skew measurement circuitry 130a determines a skew between the clock signals CLK_02b and CLK_02a′ based on a determined difference in arrival time of the clock signals.

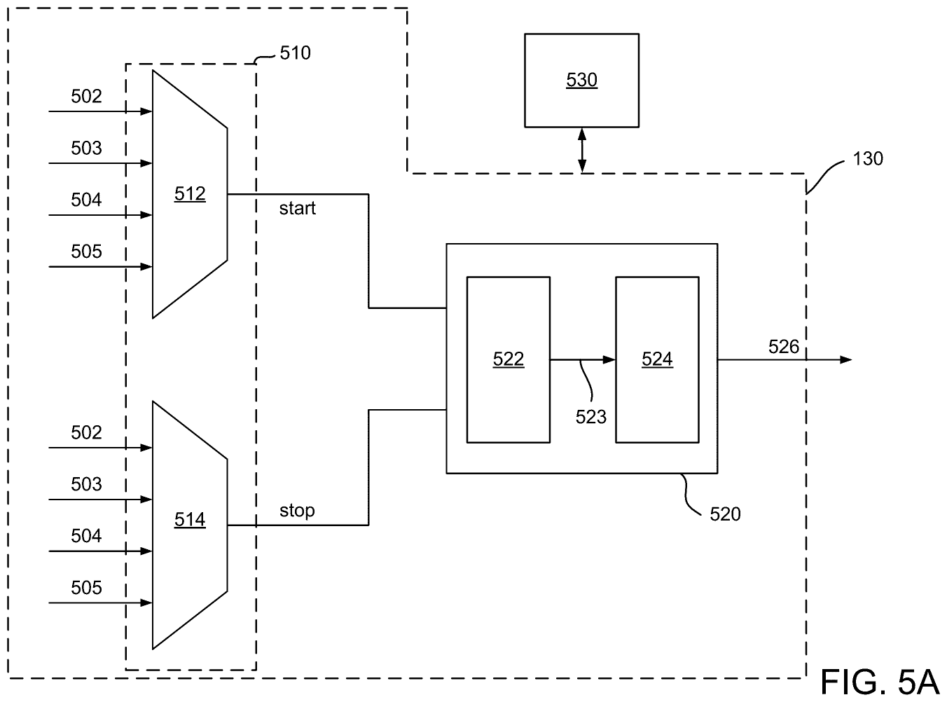

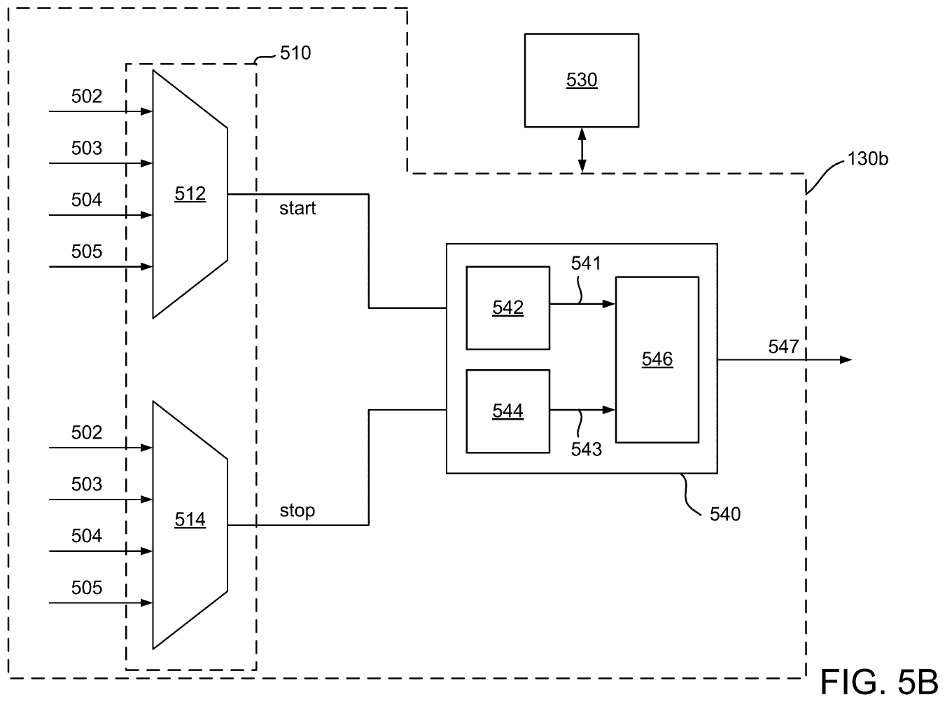

FIG. 5A illustrates a block diagram of a clock skew measurement circuitry 130. The clock skew measurement circuitry 130 includes selection circuitry 510 and error detection circuitry 520. The output of the selection circuitry 510 is coupled to inputs of the error detection circuitry 520. In one example, the selection circuitry 510 receives signals (leaf clock signals) 502-505. In other examples, the selection circuitry 510 receives more than or less than four signals. The selection circuitry 510 selects and outputs a first one of the signals 502-505 as the start signal. The selection circuitry 510 selects and outputs a second one of the signals 502-505 as the stop signal. The start and stop signals are received by the error detection circuitry 520. The error detection circuitry 520 determines a skew (timing difference) between the selected signals. The skew is determined based on a difference in phase between the selected signals. The error detection circuitry 520 outputs an error signal 526. The error signal 526 includes an indication as to whether or not there is skew (determined based on a difference in phase) between the selected signals. In one example, the error signal 526 is a phase error between the leaf clock signals.

The signals 502-505 are leaf clock signals. With reference to FIG. 3, the signals 502-505 correspond to clock signals CLK_01a, CLK_01b, CLK_02a, and CLK02b. With reference to FIG. 4, the signals 502-505 correspond to the clock signals CLK_01a, CLK_01b′, CLK_02a, and CLK02b′, or the clock signals CLK_01a′, CLK_01b, CLK_02a′, and CLK02b. In an example where the clock skew measurement circuitry 130 of FIG. 5A corresponds to the clock skew measurement circuitry 130c of FIG. 4, the signals 502-505 correspond to the clock signals CLK_01a, CLK_01b′, CLK_02a, and CLK02b′. In an example where the clock skew measurement circuitry 130 of FIG. 5A corresponds to the clock skew measurement circuitry 130a of FIG. 4, the signals 502-505 correspond to the clock signals CLK_01a′, CLK_01b, CLK_02a′, and CLK02b.

In one or more examples, the selection circuitry 510 includes a multiplexer circuitry 512 and a multiplexer circuitry 514. The multiplexer 512 has inputs that receive the signals 502-505. In other examples, the multiplexer circuitry 512 receives more than or less than four signals. The multiplexer circuitry 512 selects one of the signals 502-505. The multiplexer 512 outputs the selected of the signals 502-505. In one or more examples, the multiplexer circuitry 512 receives a control signal that indicates which of the signals 502-505 to select and output. In one example, the control signal is provided via register circuitry 530. The register circuitry 530, or circuitry connected to the register circuitry 530 generates the control signals. The control signal is generated based on which of the signals 502-505 that are to be analyzed by the error detection circuitry 520. In one example, the control signals are generated to select a first two of the signals 502-505 during a first period and a second two of the signals 502-505 during a second period. For example, during a first period a first control signal is generated and output to the multiplexer circuitry 512 to provide an indication to the multiplexer circuitry 512 to select and output the signal 502, and a second control signal is generated and output to the multiplexer circuitry 514 to provide an indication to the multiplexer circuitry 514 to select and output the signal 503. During a second period a third control signal is generated and output to the multiplexer circuitry 512 to provide an indication to the multiplexer circuitry 512 to select and output the signal 504, and a fourth control signal is generated and output to the multiplexer circuitry 514 to provide an indication to the multiplexer circuitry 514 to select and output the signal 505. The signal output by the multiplexer circuitry 512 is provided to the error detection circuitry 520 as the start signal. The multiplexer 514 has inputs that receive the signals 502-505. In other examples, the multiplexer circuitry 514 receives more than or less than four signals. The multiplexer circuitry 514 selects one of the signals 502-505. The multiplexer 514 outputs the selected of the signals 502-505. In one or more examples, the multiplexer 514 receives a control signal that indicates which of the signals 502-505 to select and output. The signal output by the multiplexer 514 is provided to the error detection circuitry 520 as the stop signal. While the multiplexer circuitries 512 and 514 are shown as receiving the same signal 502-504, in other examples, one or more signals received by the multiplexers 512 and 514 may differ, and/or the number of signals received by the multiplexer circuitries 512 and 514 may differ from that shown in FIG. 5A. For example, the multiplexer circuitry 512 may receive a greater number of signals or a smaller number of signals than the multiplexer circuitry 514.

The error detection circuitry 520 receives the start and stop signals. The error detection circuitry 520 determines whether or not skew exists between the start and stop signals. In one example, the error detection circuitry 520 compares the start signal with the stop signal to determine whether or not skew exists between the start and stop signals. In one or more examples, comparing the start and stop signals includes determining a difference between the start and stop signals. In other examples, the comparison may include methods other than or in addition to determining a difference between the start and stop signals to determine whether or not skew exists between the start and stop signals.

The error signal 526 is output to a memory device (e.g., a register or other memory device). In one example, the error signal 526 is used to adjust the timing of the corresponding clock signals to mitigate skew between clock signals. In other examples, the error signal 526 may be used to adjust a design of the corresponding to IC device to mitigate skew between clock signals.

In one example, the error detection circuitry 520 includes delay circuitry 522 and decoder circuitry 524. The delay circuitry 522 determines skew (e.g., arrival timing difference) between the start and stop signals. The delay circuitry 522 outputs the signal 523. The signal 523 is indicative of skew between the start and stop signals. The signal 523 may be coded. The decoder circuitry 524 decodes the signal 523 to generate the error signal 526. In one example, the signal 523 is a thermal code. The decoder circuitry 524 decodes the thermal code (or other code type) of the signal 523 to generate the error signal 526. The error signal 526 may have a binary code. In other example, the error signal 526 may be a different code type.

In one example, the delay circuitry 522 is calibrated based on test clock signals having a known skew. The delay circuitry 522 compares the clock signals to determine a skew measurement. The measured skew is determined to the skew of the test clock signals. A difference between the measured skew and the skew of the test clock signals is used to adjust the delay timings of the delay circuitries 610 and 620, to adjust the sampling timings of the delay circuitry 522.

FIG. 5B illustrates a block diagram of an alternative clock skew measurement circuitry 130b. In one or more examples, the clock skew measurement circuitry 130b is used instead of the clock skew measurement circuitry 130 of FIG. 1. The clock skew measurement circuitry 130b is configured similar to that of the clock skew measurement circuitry 130 of FIG. 5A. The clock skew measurement circuitry 130b includes selection circuitry 510 and error detection circuitry 540. The output of the selection circuitry 510 is coupled to inputs of the error detection circuitry 540. In one example, the selection circuitry 510 receives signals (leaf clock signals) 502-505 and is functions as described above as described with regard to FIG. 5A.

The error detection circuitry 540 is configured as described above with regard to the error detection circuitry 540 to determine a skew (timing difference) between the selected signals. The skew is determined based on a difference in phase between the selected signals. The error detection circuitry 540 outputs an error signal 547. The error signal 547 includes an indication as to whether or not there is skew (determined based on a difference in phase) between the selected signals. In one example, the error signal 547 is a phase error between the leaf clock signals.

The error detection circuitry 540 receives the start and stop signals. The error detection circuitry 540 determines whether or not skew exists between the start and stop signals. In one example, the error detection circuitry 540 compares the start signal with the stop signal to determine whether or not skew exists between the start and stop signals. In one or more examples, comparing the start and stop signals includes determining a difference between the start and stop signals. In other examples, the comparison may include methods other than or in addition to determining a difference between the start and stop signals to determine whether or not skew exists between the start and stop signals.

The error signal 547 is output to a memory device (e.g., a register or other memory device). In one example, the error signal 547 is used to adjust the timing of the corresponding clock signals to mitigate skew between clock signals. In other examples, the error signal 547 may be used to adjust a design of the corresponding to IC device to mitigate skew between clock signals.

In one example, the error detection circuitry 540 includes coarse delay circuitry 542, fine delay circuitry 544, and decoder circuitry 546. The coarse delay circuitry 542 and the fine delay circuitry 544 determine skew (e.g., arrival timing difference) between the start and stop signals as is described above with regard to the delay circuitry 522. The coarse delay circuitry 542 has a wider resolution than the fine delay circuitry 544. The coarse delay circuitry 542 covers a larger range and the fine delay circuitry 544 covers a smaller range with a higher resolution than the coarse delay circuitry 542. The coarse delay circuitry 542 outputs a coarse output signal 541 to the decoder circuitry 546. The coarse output signal 541 corresponds to a phase difference (e.g., a timing difference or skew) between the start and stop signals. The fine delay circuitry 544 outputs a fine output signal 543 to the decoder circuitry 546. The fine output signal 543 corresponds to a phase difference (e.g., a timing difference or skew) between the start and stop signals. In one example, the coarse delay circuitry 542 determines the skew, when the skew is large (e.g., out of the range of the fine delay circuitry 544). In one example, the range of the fine delay circuitry 544 overlaps with the range of the coarse delay circuitry 542. In one example, when the output of the fine delay circuitry 544 is output of the range of the fine delay circuitry 544, the error signal 547 is generated based on the coarse output signal 541. In one example, when the output of the fine delay circuitry 544 is within the range of the fine delay circuitry 544, the error signal 547 is generated based on the fine output signal 543.

Using the coarse delay circuitry 542 and the fine delay circuitry 544 increases the range and/or resolution of skew that can be determined by the error detection circuitry 540.

The coarse output signal 541 and the fine output signal 543 are indicative of skew between the start and stop signals. The coarse output signal 541 and the fine output signal 543 may be coded. The decoder circuitry 546 decodes the coarse output signal 541 and/or the fine output signal 543 to generate the error signal 547. In one example, the coarse output signal 541 and/or the fine output signal 543 are thermal codes. The decoder circuitry 546 decodes the thermal code (or other code type) of the signal 523 to generate the error signal 547. The error signal 547 may have a binary code. In other example, the error signal 547 may be a different code type.

In one or more examples, the coarse delay circuitry 542 and/or the fine delay circuitry 544 are calibrated as described above with regard to the delay circuitry 522.

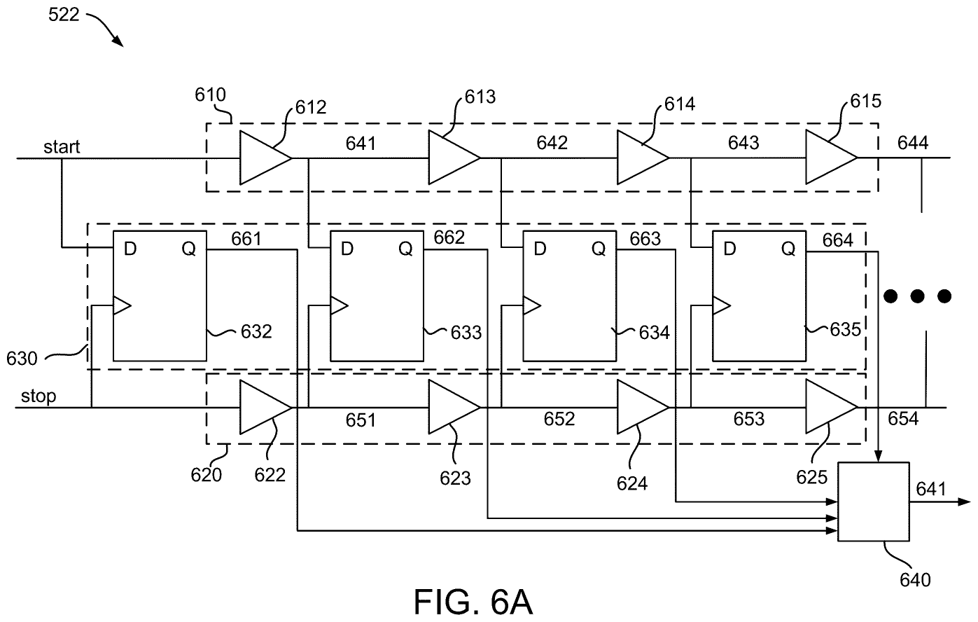

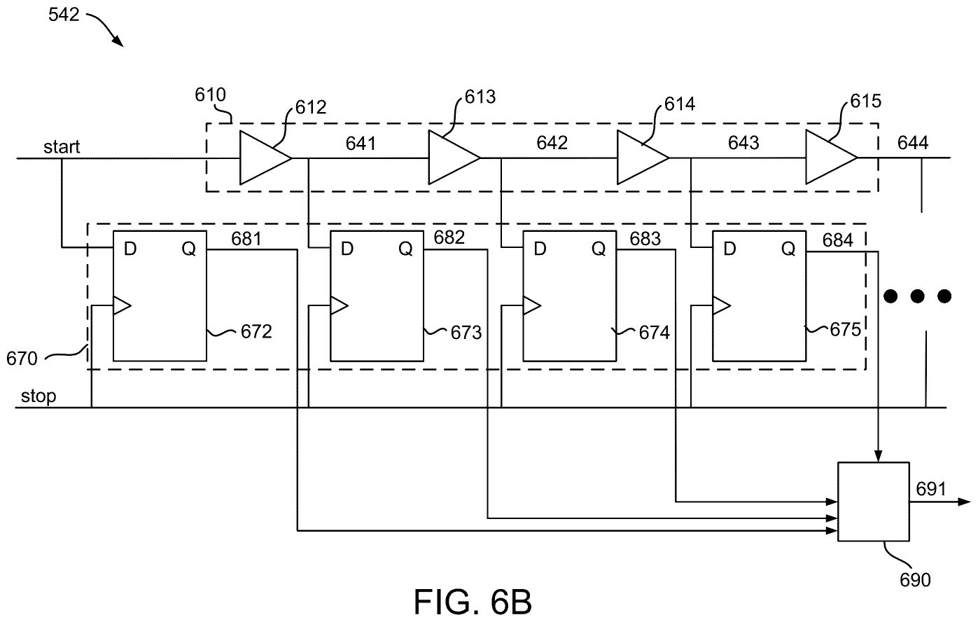

FIG. 6A illustrates a block schematic diagram of the delay circuitry 522. The delay circuitry 522 includes delay circuitry 610, delay circuitry 620, flip-flop circuitry 630, and combiner circuitry 640. The delay circuitry 610 includes delay circuitries 612-615. Each of the delay circuitry 612-615 corresponds to a different delay stage. In one or more examples, the delay circuitry 610 includes more than four delay circuitries, and more than four delay stages. The delay circuitry 620 includes delay circuitries 622-625. Each of the delay circuitry 622-625 corresponds to a different delay stage. In one or more examples, the delay circuitry 610 includes more than four delay circuitries, and more than four delay stages.

The flip-flop circuitry 630 includes flip-flops 632- 635. In other examples, the flip-flops circuitry 630 includes more than four flip-flops 632-635. In one or more examples, the number of flip-flops 632-635 is equal to the number of delay circuitries 612-615, which is equal to the number delay circuitries 622-625.

The delay circuitries 610 and the flip-flop circuitries 630 receive the start signal. The delay circuitries 620 and the flip-flop circuitries 630 receive the stop signal. The output of one or more of the delay circuities 612-615 is received by a respective one of the flip-flops 633-635. The output of one or more of the delay circuities 622-625 is received by a respective one of the flip-flops 633-635.

In one example, the delay circuitry 612 receives the start signal, delays the start signal, and outputs a delayed signal 641. The delay circuitry 613 receives the signal 641, delays the signal 641, and outputs a delayed signal 642. The delay circuitry 614 receives the signal 642, delays the signal 642, and outputs a delayed signal 643. The delay circuitry 615 receives the signal 643, delays the signal 643, and outputs a delayed signal 644.

The delay circuitry 622 receives the stop signal, delays the stop signal, and outputs a delayed signal 651. The delay circuitry 623 receives the signal 651, delays the signal 651, and outputs a delayed signal 652. The delay circuitry 624 receives the signal 652, delays the signal 652, and outputs a delayed signal 653. The delay circuitry 625 receives the signal 653, delays the signal 653, and outputs a delayed signal 654.

The flip-flop 632 receives the start signal at a data input, the stop signal at a reset input, and outputs the signal 631 based on the start and stop signals. The flip-flop 633 receives the signal 641 at a data input, the signal 651 at a reset input, and outputs the signal 662 based on the signals 641 and 651. The flip-flop 634 receives the signal 642 at a data input, the signal 652 at a reset input, and outputs the signal 663 based on the signals 642 and 652. The flip-flop 635 receives the signal 643 at a data input, the signal 653 at a reset input, and outputs the signal 664 based on the signals 643 and 653.

The signals 661-664 are received by the combiner circuitry 640. The combiner circuitry 640 generates and outputs the signal 641 based on the signals 661-664. In one example, the combiner circuitry 640 is summation circuitry and sums the values of the signals 661-664 to generate the signal 641. In other examples, the combiner circuitry 640 is another type of circuitry that is used to combine the signals 661-664 to generate the signal 641.

In one or more examples, the delay of the delay circuitries 610 is greater than the delay of the delay circuitries 620. Further, as the start and stop signals propagate through the delay circuitries 610 and the delay circuities 620, the time difference between the start and stop signals is decreased in each delay stage by the difference in the delays of the delay circuitries 610 and the delay circuitries 620. The flip-flops 632-635 decide whether the output of a respective delay circuitry 612-615 or an output of a respective delay circuitry 622-625 has a logic high (or logic low) value first. The position in the delay circuitry 522 at which the stop signal catches up to the start signal provides information related to the measured time between the start and stop signals. In one example, a segment of the delay circuitry 522 corresponds to an output of a delay circuitry 610 and an output of a delay circuitry 620. The delay for a segment is Tdly=Tdly1−Tdly2, where Tdly1 is the delay of the delay circuitries 610, and Tdly2 is the delay of the delay circuitries 620.

In one example, the delay circuitry 522 includes 100 or more delay stages. In other examples, the delay circuitry 522 includes 500 or more delay stages. The number of delay stages provides a resolution of the delay circuitry 522.

With reference to FIG. 5B, the fine delay circuitry 544 is configured similar to the delay circuitry 522 illustrated in FIG. 6A. FIG. 6B illustrates a block schematic diagram of the coarse delay circuitry 542. The coarse delay circuitry 542 includes the delay circuitry 610, flip-flop circuitry 670, and combiner circuitry 690. The delay circuitry 610 includes delay circuitries 612-615 and is described in greater detail above with regard to FIG. 6A.

The flip-flop circuitry 680 includes flip-flops 672-675. In other examples, the flip-flops circuitry 670 includes more than four flip-flops 672-675. In one or more examples, the number of flip-flops 672-675 is equal to the number of delay circuitries 612-615, which is equal to the number delay circuitries 622-625.

The delay circuitries 610 and the flip-flop circuitries 670 receive the start signal. The delay circuitries 620 and the flip-flop circuitries 670 receive the stop signal. The output of one or more of the delay circuities 612-615 is received by a respective one of the flip-flops 673-675. The output of one or more of the delay circuities 622-625 is received by a respective one of the flip-flops 673-675.

Each of the flip-flops 672-675 receive the stop signal at a reset input. The flip-flop 672 receives the start signal at a data input, and outputs the signal 681 based on the start and stop signals. The flip-flop 673 receives the signal 641 at a data input, and outputs the signal 682 based on the signals 641 and the stop signal. The flip-flop 674 receives the signal 642 at a data input, and outputs the signal 687 based on the signals 642 and the stop signal. The flip-flop 675 receives the signal 643 at a data input, and outputs the signal 684 based on the signals 643 and the stop signal.

The signals 681-684 are received by the combiner circuitry 690. The combiner circuitry 690 generates and outputs the signal 691 based on the signals 681-684. In one example, the combiner circuitry 690 is summation circuitry and sums the values of the signals 681-684 to generate the signal 691. In other examples, the combiner circuitry 690 is another type of circuitry that is used to combine the signals 681-684 to generate the signal 691.

The flip-flops 672-675 decide whether the output of a respective delay circuitry 612-615 or the stop signal has a logic high (or logic low) value first. The timing of the stop signal at which the stop signal catches up to the start signal provides information related to the measured time between the start and stop signals.

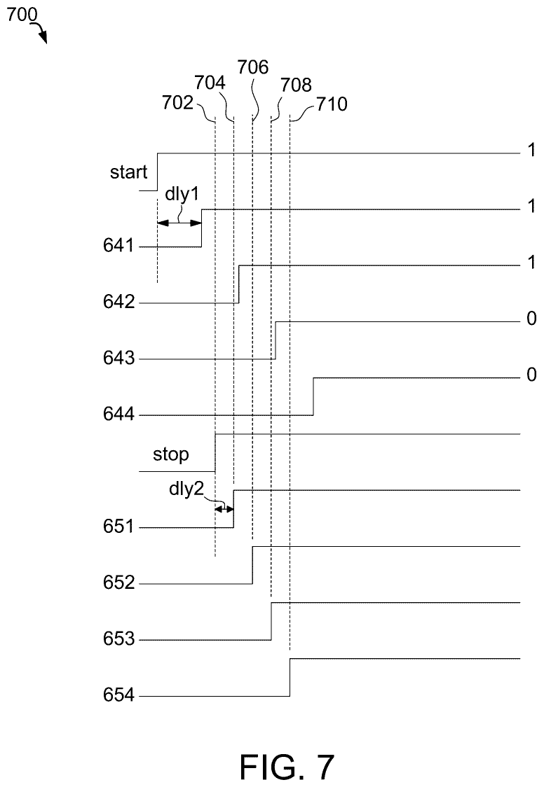

FIG. 7 illustrates waveforms 700 of start and stop signals, and the corresponding delayed signals of the delay circuitry 522 of FIG. 6A. The signals start and signals 641-644 are sampled at sampling times 702-708. Sampling times 702-708 corresponds to a rising edge of the signals stop and signals 651-654. For example, the start signal is sampled at sampling time 702 to provide a value of 1. The signal 641 is sampled at sampling time 704 to provide a value of 1. The signal 642 is sampled at sampling time 706 to provide a value of 1. The signal 643 is sampled at sampling time 708 to provide a value of 0. The signal 644 is sampled at sampling time 710 to provide a value of 0. The sampled values (e.g., a value of 0 or 1) are output to the combiner circuitry 640 to determine the skew between the start and stop signals. In one example, the error signal 526 is generated from the output values “11100” (e.g., the signal 523). In one example, the values 111 can be decoded to be “3”. In other examples, the values 111 may be decoded to have a different code.

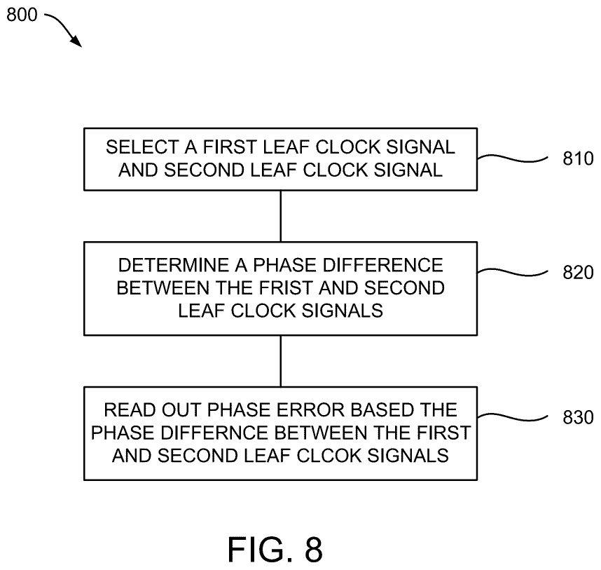

FIG. 8 illustrates a flowchart of a method 800 for determining skew between clock signals. At 810 of the method 800, first and second leaf clock signals are selected. For example, with reference to FIG. 5A or FIG. 5B, the selection circuitry 510 selects a first leaf clock signal and a second leaf clock from the leaf clock signals 502-505. In one example, the multiplexer circuitry 512 receives the leaf clock signals 502-505 and selects a first one of the leaf clock signals. The multiplexer circuitry 514 receives the leaf clock signals 502-505 and selects a second one of the leaf clock signals. The leaf clock signals 502-505 are the clock signals at different leafs of a clock tree.

At 820 of the method 800, a phase difference between the first and second leaf clock signals is determined. For example, with reference to FIG. 5A or FIG. 5B, the error detection circuitry 520 or the error detection circuitry 540 receives the selected first and second leaf clock signals and determines a phase difference between the first and second leaf clock signals. The phase difference corresponds to the skew between the first and second leaf clock signals. In one example, the phase difference between the first and second leaf clock signals is determined by comparing the first leaf clock signal from the second leaf clock signal. The comparison is performed by the delay circuitry 522 of FIG. 5 and FIG. 6A or the coarse delay circuitry 542 and/or the fine delay circuitry 544 of FIG. 5B, FIG. 6A, and FIG. 6B. In one example, the comparison may be referred to as a subtraction operation. With reference to FIG. 3, the selected first leaf clock signal corresponds to the leaf clock signal CLK_01a and the selected second leaf clock signal corresponds to the leaf clock signal CLK_01b. The leaf clock signal CLK_01a is compared to the leaf clock signal CLK_01b to determine skew between the leaf clock signals CLK_01a and CLK_01b. For example, the leaf clock signal CLK_01a is the start signal and the leaf clock signal CLK_01b is the stop signal. The delay circuitry 522 is used to determine skew between the leaf clock signals CLK_01a and CLK_01b. In another example, the selected first leaf clock signal corresponds to the leaf clock signal CLK_02a and the selected second leaf clock signal corresponds to the leaf clock signal CLK_02b. The leaf clock signal CLK_02a is compared to the leaf clock signal CLK_02b to determine skew between the leaf clock signals CLK_02a and CLK_02b. For example, the leaf clock signal CLK_02a is the start signal and the leaf clock signal CLK_02b is the stop signal. The delay circuitry 522 is used to determine phase difference between the leaf clock signals CLK_02a and CLK_02b.

With reference to FIG. 4, the selected first leaf clock signal corresponds to the leaf clock signal CLK_01a and the selected second leaf clock signal corresponds to the leaf clock signal CLK_01b′. The leaf clock signal CLK_01a is compared to the leaf clock signal CLK_01b′ to determine a phase difference between the leaf clock signals CLK_01a and CLK_01b′. For example, the leaf clock signal CLK_01a is the start signal and the leaf clock signal CLK_01b′ is the stop signal. The delay circuitry 522 is used to determine the phase difference between the leaf clock signals CLK_01a and CLK_01b′.

In one example, the selected first leaf clock signal corresponds to the leaf clock signal CLK_02a and the selected second leaf clock signal corresponds to the leaf clock signal CLK_02b′. The leaf clock signal CLK_02a is compared to the leaf clock signal CLK_02b′ to determine skew between the leaf clock signals CLK_02a and CLK_02b′. For example, the leaf clock signal CLK_02a is the start signal and the leaf clock signal CLK_02b′ is the stop signal. The delay circuitry 522 is used to determine the phase difference between the leaf clock signals CLK_02a and CLK_02b′.

In one example, the selected first leaf clock signal corresponds to the leaf clock signal CLK_01b and the selected second leaf clock signal corresponds to the leaf clock signal CLK_01a′. The leaf clock signal CLK_01b is compared to the leaf clock signal CLK_01a′ to determine skew between the leaf clock signals CLK_01b and CLK_01a′. For example, the leaf clock signal CLK_01b is the start signal and the leaf clock signal CLK_01a′ is the stop signal. The delay circuitry 522 is used to determine the phase difference between the leaf clock signals CLK_01b and CLK_01a′.

In one example, the selected first leaf clock signal corresponds to the leaf clock signal CLK_02b and the selected second leaf clock signal corresponds to the leaf clock signal CLK_02a′. The leaf clock signal CLK_02b is compared to the leaf clock signal CLK_02a′ to determine the phase difference between the leaf clock signals CLK_02b and CLK_02a′. For example, the leaf clock signal CLK_02b is the start signal and the leaf clock signal CLK_02a′ is the stop signal. The delay circuitry 522 is used to determine the phase difference between the leaf clock signals CLK_02b and CLK_02a′.

In one example to mitigate skew between IC devices (e.g., between the IC device 100a and 100c), two skew measurements are determined. For example, a first skew between the IC device 100c and the IC device 100a is determined, and a skew difference between the IC device 100a and the IC device 100c is determined. To determine skew between the IC device 100c and 100a, a skew measurement of Skew1 is determined between leaf clock signals CLK_01b′ and CLK_01a. For example, the leaf clock signal CLK_01b′ is selected as the start signal and the leaf clock signal CLK_01a is selected as the stop signal. In one example, Skew1=CLK_01b′-CLK_01a. To determine skew between the IC device 100a and 100c, a skew measurement of Skew2 is determined between leaf clock signals CLK_01a′ and CLK_01b. For example, the leaf clock signal CLK_01a′ is selected as the start signal and the leaf clock signal CLK_01b is selected as the stop signal. Skew2=CLK_01a′-CLK_01b. A difference between Skew1 and Skew2 is determined. The difference between Skew1 and Skew2 is equal to two times the difference between CLK_01b and CLK_01a, or Skew1−Skew2=2*(CLK_01b−CLK_01a).

At 830 of the method 800, phase error is read out based on the phase difference between the first and second leaf signals. For example, with reference to FIG. 5A or the FIG. 5B, the error signal 526 or the error signal 547 is generated based on the phase difference determined between the first and second leaf signals. The error signal 526 or the error signal 547 includes an indication as to whether or not there is skew (e.g., a phase difference) between the first and second leaf signals. In one or more examples, the error signal 526 or the error signal 547 includes an indication as to the amount of phase difference between the first and second leaf signals. In one example, the error signal 526 or the error signal 547 is output to a memory device (e.g., a register or other memory device). In one example, the error signal 526 or the error signal 547 is used to adjust the timing of the corresponding clock signals to mitigate skew between clock signals. In other examples, the error signal 526 or the error signal 547 may be used to adjust a design of the corresponding to IC device to mitigate skew between clock signals.

While the foregoing is directed to specific examples, other and further examples may be devised without departing from the basic scope thereof, and the scope thereof is determined by the claims that follow.

What is claimed is:

1. An integrated circuit (IC) device comprising:
clock tree circuitry configured to provide a first clock signal and a second clock signal to components of the IC device; and
clock skew measurement circuitry connected to the clock tree circuitry and configured to:
generate and output an error signal based on a phase difference between the first clock signal and the second clock signal.

2. The IC device of claim 1, wherein the clock skew measurement circuitry further comprises delay circuitry configured to apply a first delay to the first clock signal and a second delay to the second clock signal to determine the phase difference.

3. The IC device of claim 2, wherein the first delay is greater than the second delay.

4. The IC device of claim 2, wherein the clock skew measurement circuitry comprises selection circuitry configured to select the first clock signal and the second clock signal from a plurality of clock signals, and output the first clock signal and the second clock signal to the delay circuitry.

5. The IC device of claim 4, wherein the delay circuitry is configured to sample the first clock signal based on the second clock signal.

6. The IC device of claim 1, wherein the clock skew measurement circuitry is further configured to receive a third clock signal from a second IC device, and determine a phase difference between the third clock signal and the first clock signal.

7. The IC device of claim 6, wherein the clock skew measurement circuitry is along a boundary of the IC device.

8. An electronic device comprising:
a first integrated circuit (IC) device comprising:
clock tree circuitry configured to provide a first clock signal and a second clock signal to components of the IC device; and
a clock skew measurement circuitry connected to the clock tree circuitry and configured to:
generate and output an error signal based on a phase difference between the first clock signal and the second clock signal.

9. The electronic device of claim 8, wherein the clock skew measurement circuitry further comprises delay circuitry configured to apply a first delay to the first clock signal and a second delay to the second clock signal to determine the phase difference.

10. The electronic device of claim 9, wherein the first delay is greater than the second delay.

11. The electronic device of claim 9, wherein the clock skew measurement circuitry comprises selection circuitry configured to select the first clock signal and the second clock signal from a plurality of clock signals, and output the first clock signal and the second clock signal to the delay circuitry.

12. The electronic device of claim 11, wherein the delay circuitry is configured to sample the first clock signal based on the second clock signal.

13. The electronic device of claim 8 further comprising a second IC device connected to the first IC device, and wherein the clock skew measurement circuitry is further configured to receive a third clock signal from the second IC device, and determine a phase difference between the third clock signal and the first clock signal.

14. The electronic device of claim 13, wherein the clock skew measurement circuitry is along a boundary of the IC device.

15. A method comprising:
receiving, at clock skew measurement circuitry of a first integrated circuit (IC) device, a first clock signal and a second clock signal from clock tree circuitry of the IC device; and
generating and outputting, via the clock skew measurement circuitry, an error signal based on a phase difference between the first clock signal and the second clock signal.

16. The method of claim 15 further comprising applying, via delay circuitry of the clock skew measurement circuitry, a first delay to the first clock signal and a second delay to the second clock signal to determine the phase difference.

17. The method of claim 16 further comprising selecting, via selection circuitry of the clock skew measurement circuitry, the first clock signal and the second clock signal from a plurality of clock signals, and outputting the first clock signal and the second clock signal to the delay circuitry.

18. The method of claim 17 further comprising sampling the first clock signal and the second clock signal based on the second clock signal.

19. The method of claim 15 further comprising receiving, by the clock skew measurement circuitry, a third clock signal from a second IC device, and determining a phase difference between the third clock signal and the first clock signal.

20. The method of claim 19, wherein the clock skew measurement circuitry is along a boundary of the IC device.
